(19) United States
(12) Patent Application Publication
(10) Pub. No.: US 2026/0357868 A1
(43) Pub. Date: Nov. 12, 2026

(54) VIBRATION DAMPING STRUCTURE FOR VEHICLE AND VEHICLE

(71) Applicant: Coretronic Intelligent Robotics Corporation, Hsin-Chu (TW)

(72) Inventors: I-Wei Chiu, Hsin-Chu (TW); Ying-Chieh Chen, Hsin-Chu (TW); I-Ta Yang, Hsin-Chu (TW); Tai-Yuan Wang, Hsin-Chu (TW)

(73) Assignee: Coretronic Intelligent Robotics Corporation, Hsin-Chu (TW)

(21) Appl. No.: 19/654,405

(22) Filed: Apr. 21, 2026

Related U.S. Application Data
(60) Provisional application No. 63/802,625, filed on May 9, 2025.

(30) Foreign Application Priority Data
Jul. 15, 2025 (TW) 114126781

(51) Int. Cl. F16F 15/08; B64D 31/04; H05K 5/00; H05K 5/02

(52) U.S. Cl. CPC F16F 15/08; B64D 31/04; H05K 5/0026; H05K 5/0217

(57) ABSTRACT

A vibration damping structure for a vehicle configured to connect a mounted object to a main body of the vehicle and including multiple vibration damping modules is provided. Each vibration damping module includes first and second positioning plates and first and second damping balls. The first positioning plate is fixed to the main body. The second positioning plate is located at a side of the first positioning plate away from the main body and fixed to the mounted object. The first and second positioning plates have opposite first and second ends, respectively. The first and second damping balls contact the main body, respectively. the first ends of the first and second positioning plates are respectively sleeved onto two opposite ends of the first damping ball, and the second ends of the first and second positioning plates are respectively sleeved onto two opposite ends of the second damping ball.

### CROSS-REFERENCE TO RELATED APPLICATION

This application claims the priority benefit of U.S. provisional application serial no. 63/802,625, filed on May 9, 2025, and Taiwan application serial no. 114126781, filed on Jul. 15, 2025. The entirety of each of the above-mentioned patent applications is hereby incorporated by reference herein and made a part of this specification.

### BACKGROUND

### Technical Field

The disclosure relates to a vibration damping structure, and particularly relates to a vibration damping structure for a vehicle and the vehicle.

### Description of Related Art

Common mobile vehicles include automobiles, vessels, or aircraft. During operation, the mobile vehicle may be affected by a power source (such as an engine or motor), terrain, water flow, air flow, operation path, operation speed, operation state, or other factors and generate vibrations that are further transmitted to the instruments mounted thereon. In detail, when the vibration is transmitted to the instruments, it may affect the reliability, accuracy, or durability of precision components therein, and even cause functional failure or damage.

The information disclosed in this Background section is only for enhancement of understanding of the background of the described technology and therefore it may contain information that does not form the prior art that is already known to a person of ordinary skill in the art. Further, the information disclosed in the Background section does not mean that one or more problems to be resolved by one or more embodiments of the disclosure was acknowledged by a person of ordinary skill in the art.

### SUMMARY

The disclosure provides a vibration damping structure for a vehicle configured to connect a mounted object to a main body of the vehicle. The vibration damping structure for the vehicle includes a plurality of vibration damping modules. Each vibration damping module includes a first positioning plate, a second positioning plate, a first damping ball, and a second damping ball. The first positioning plate is configured to be fixed to the main body and has a first end and a second end opposite to each other. The second positioning plate is located at a side of the first positioning plate away from the main body and is configured to be fixed to the mounted object. The second positioning plate has a first end and a second end opposite to each other. The first damping ball is configured to contact the main body, and the first end of the first positioning plate and the first end of the second positioning plate are respectively sleeved onto two opposite ends of the first damping ball. The second damping ball is configured to contact the main body, and the second end of the first positioning plate and the second end of the second positioning plate are respectively sleeved onto two opposite ends of the second damping ball.

The disclosure provides a vehicle including a main body and a vibration damping structure for the vehicle disposed on the main body. The vibration damping structure for the vehicle includes a plurality of vibration damping modules. Each vibration damping module includes a first positioning plate, a second positioning plate, a first damping ball, and a second damping ball. The first positioning plate is fixed to the main body and has a first end and a second end opposite to each other. The second positioning plate is located at a side of the first positioning plate away from the main body and has a first end and a second end opposite to each other. The first damping ball contacts the main body, and the first end of the first positioning plate and the first end of the second positioning plate are respectively sleeved onto two opposite ends of the first damping ball. The second damping ball contacts the main body, and the second end of the first positioning plate and the second end of the second positioning plate are respectively sleeved onto two opposite ends of the second damping ball.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

FIG. 1A is a schematic view of a vehicle according to an embodiment of the disclosure.

FIG. 1B is a schematic view of a vibration damping structure for a vehicle fixed to a mounted object according to an embodiment of the disclosure.

FIG. 1C is a schematic side view of the vibration damping structure for the vehicle of FIG. 1B configured to connect the mounted object to the main body of the vehicle.

FIG. 1D is a schematic view of the vibration damping module of FIG. 1B.

FIG. 1E is a schematic bottom view of the mounted object and the vibration damping structure for the vehicle of FIG. 1B.

FIG. 1F is a schematic exploded view of the vibration damping module of FIG. 1B.

FIG. 2A is a schematic view of the flight control box of FIG. 1B.

FIG. 2B is a schematic exploded view of the flight control box of FIG. 2A.

FIG. 2C is a schematic cross-sectional view along line segment 2C-2C of FIG. 2A.

### DESCRIPTION OF THE EMBODIMENTS

In the following detailed description of the preferred embodiments, reference is made to the accompanying drawings which form a part hereof, and in which are shown by way of illustration specific embodiments in which the invention may be practiced. In this regard, directional terminology, such as "top," "bottom," "front," "back," etc., is used with reference to the orientation of the Figure(s) being described. The components of the present invention can be positioned in a number of different orientations. As such, the directional terminology is used for purposes of illustration and is in no way limiting. On the other hand, the drawings are only schematic and the sizes of components may be exaggerated for clarity. It is to be understood that other embodiments may be utilized and structural changes may be made without departing from the scope of the present invention. Also, it is to be understood that the phraseology and terminology used herein are for the purpose of description and should not be regarded as limiting. The use of “including,” “comprising,” or “having” and variations thereof herein is meant to encompass the items listed thereafter and equivalents thereof as well as additional items. Unless limited otherwise, the terms “connected,” “coupled,” and “mounted” and variations thereof herein are used broadly and encompass direct and indirect connections, couplings, and mountings. Similarly, the terms “facing,” “faces” and variations thereof herein are used broadly and encompass direct and indirect facing, and “adjacent to” and variations thereof herein are used broadly and encompass directly and indirectly “adjacent to”. Therefore, the description of “A” component facing “B” component herein may contain the situations that “A” component directly faces “B” component or one or more additional components are between “A” component and “B” component. Also, the description of “A” component “adjacent to” “B” component herein may contain the situations that “A” component is directly “adjacent to” “B” component or one or more additional components are between “A” component and “B” component. Unless limited otherwise, the terms “connected,” “coupled,” and “mounted,” and variations thereof herein are used broadly and encompass direct and indirect connections, couplings, and mountings. Accordingly, the drawings and descriptions will be regarded as illustrative in nature and not as restrictive.

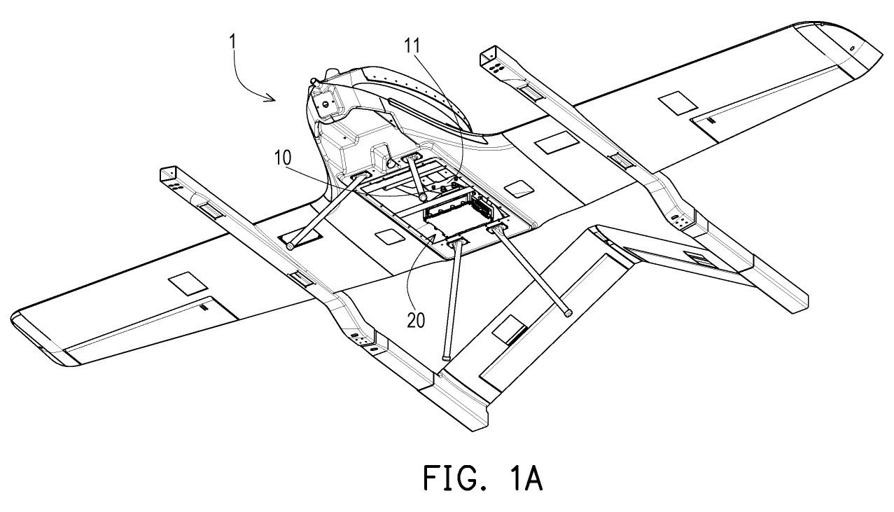

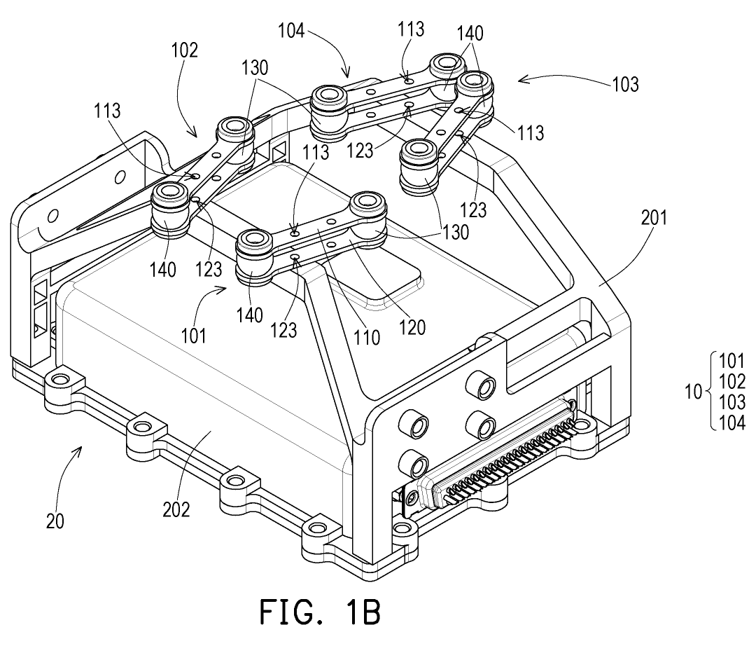

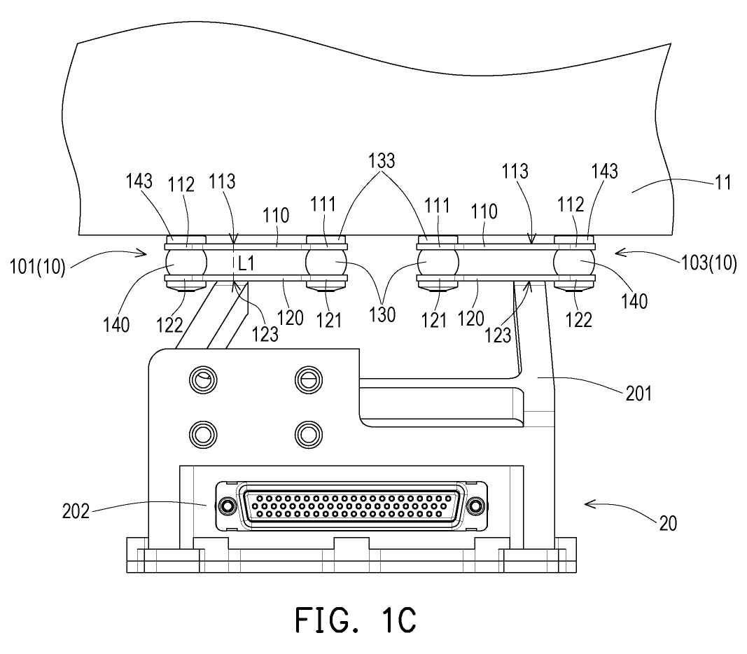

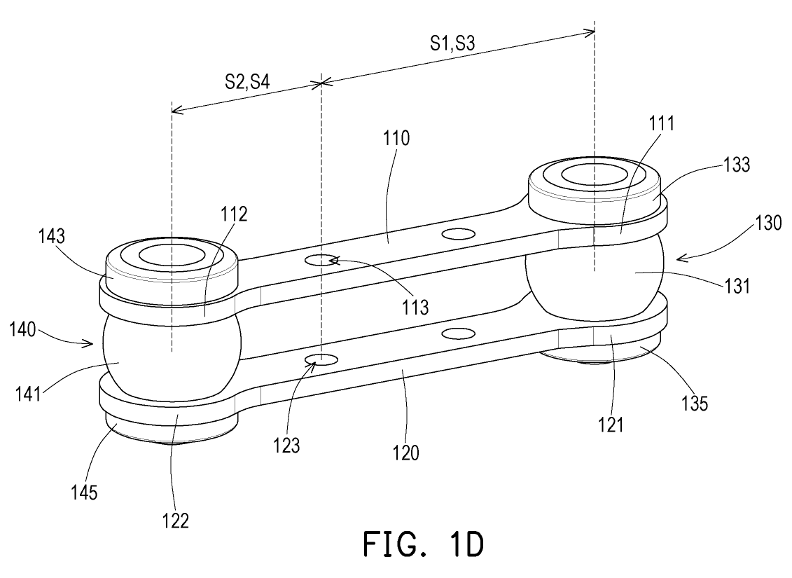

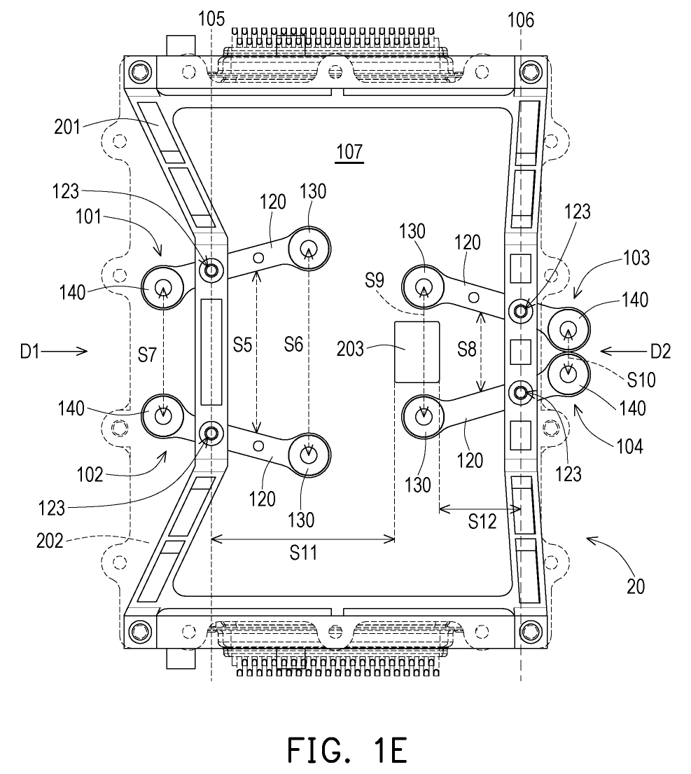

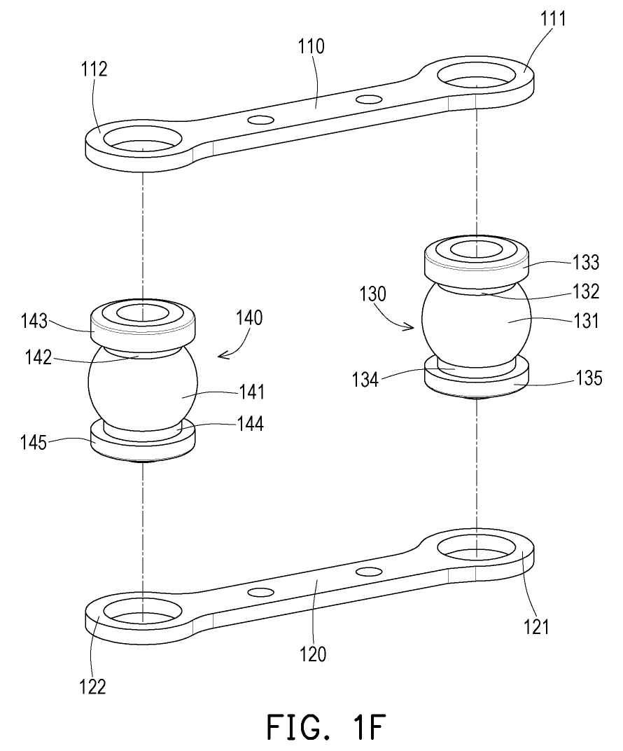

FIG. 1A is a schematic view of a vehicle according to an embodiment of the disclosure. FIG. 1B is a schematic view of a vibration damping structure for a vehicle fixed to a mounted object according to an embodiment of the disclosure. FIG. 1C is a schematic side view of the vibration damping structure for the vehicle of FIG. 1B configured to connect the mounted object to the main body of the vehicle. Referring to FIGS. 1A-1C, in the embodiment, a vehicle 1 includes a vibration damping structure for the vehicle 10, a main body 11, and a mounted object 20. The vibration damping structure for the vehicle 10 is disposed on the main body 11, and is located between the mounted object 20 and the main body 11 and configured to connect the mounted object 20 to the main body 11 of the vehicle 1.

Specifically, one side of the vibration damping structure for the vehicle 10 is fixed to the main body 11 of the vehicle 1, and the other side of the vibration damping structure for the vehicle 10 is fixed to the mounted object 20. In other words, the mounted object 20 is fixed to the main body 11 of the vehicle 1 by the vibration damping structure for the vehicle 10, so that the vibration damping structure for the vehicle 10 absorbs the vibration generated when the vehicle 1 operates, thereby significantly reducing the degree of vibration transmitted from the main body 11 to the mounted object 20 to avoid failure, damage, or functional failure of the mounted object 20 due to vibration.

In the embodiment, the vehicle 1 may be an unmanned aerial vehicle, the main body 11 may be the fuselage of the unmanned aerial vehicle, and the mounted object 20 may be fixed to the fuselage (for example, the belly, nose, or other portions of the fuselage) of the unmanned aerial vehicle by the vibration damping structure for the vehicle 10. Specifically, the mounted object 20 may include a bracket 201 and a flight control box 202 fixed to the bracket 201. The bracket 201 is positioned between the vibration damping structure for the vehicle 10 and the flight control box 202, and the vibration damping structure for the vehicle 10 is positioned between the bracket 201 and the main body 11 and configured to connect the bracket 201 to the main body 11.

Although the embodiment is described using an unmanned aerial vehicle, the disclosure is not limited thereto. In other examples, the vehicle may be a manned vehicle or an unmanned vehicle, such as an automobile, vessel, aircraft, or other mobile equipment. Furthermore, although the embodiment is described using a mounted object composed of a bracket and a flight control box. In other examples, the mounted object may be a combination of a bracket and other equipment or instruments, or may be a flight control box, gimbal, other equipment, or instruments directly fixed to the vehicle through the vibration damping structure for the vehicle.

FIG. 1D is a schematic view of the vibration damping module of FIG. 1B. Referring to FIGS. 1B-1D, in the embodiment, the vibration damping structure for the vehicle 10 includes a plurality of vibration damping modules, and may include a first vibration damping module 101, a second vibration damping module 102, a third vibration damping module 103, and a fourth vibration damping module 104, for example. Each vibration damping module has the same structural design, including a first positioning plate 110, a second positioning plate 120, a first damping ball 130, and a second damping ball 140. In detail, the first positioning plate 110 and the second positioning plate 120 of each vibration damping module are parallel to each other. The first positioning plate 110 is fixed to the main body 11, and the second positioning plate 120 is located at a side of the first positioning plate 110 away from the main body 11 to be fixed to the mounted object 20, such as the bracket 201. Alternatively, the mounted object 20 is located at a side of the second positioning plate 120 away from the main body 11 and is fixed to the second positioning plate 120, for example, by the bracket 201.

The first positioning plate 110 and the second positioning plate 120 of each vibration damping module are disposed in pairs and have the same structural design. The first positioning plate 110 has a first end 111 and a second end 112 opposite to each other, and the second positioning plate 120 also has a first end 121 and a second end 122 opposite to each other. In detail, the first end 111 of the first positioning plate 110 is aligned with the first end 121 of the second positioning plate 120, and the first end 111 of the first positioning plate 110 and the first end 121 of the second positioning plate 120 are respectively sleeved onto two opposite ends of the first damping ball 130. In addition, the second end 112 of the first positioning plate 110 is aligned with the second end 122 of the second positioning plate 120, and the second end 112 of the first positioning plate 110 and the second end 122 of the second positioning plate 120 are respectively sleeved onto two opposite ends of the second damping ball 140.

The first damping ball 130 and the second damping ball 140 of each vibration damping module both contact the main body 11. The first damping ball 130 contacts the main body 11 with an end portion passing through the first end 111 of the first positioning plate 110, and the second damping ball 140 contacts the main body 11 with an end portion passing through the second end 112 of the first positioning plate 110. In addition, the end portion of the first damping ball 130 passing through the first end 121 of the second positioning plate 120 does not contact the mounted object 20, and the end portion of the second damping ball 140 passing through the second end 122 of the second positioning plate 120 does not contact the mounted object 20.

Accordingly, the vibration generated when the vehicle 1 operates may be transmitted from the first positioning plate 110 of each vibration damping module to the first damping ball 130 and the second damping ball 140 of each vibration damping module to be absorbed, or directly transmitted to the first damping ball 130 and the second damping ball 140 of each vibration damping module to be absorbed, thereby enhancing the vibration damping effect for the mounted object 20.

Referring to FIGS. 1B-1D, in the embodiment, the first positioning plate 110 of each vibration damping module may be fixed to the main body 11 through locking, clamping, bonding, or riveting, and the second positioning plate 120 may be fixed to the mounted object 20, such as the bracket 201, through locking, clamping, bonding, or riveting. In detail, the bracket 201 is positioned between the flight control box 202 and each vibration damping module, and each vibration damping module is positioned between the bracket 201 and the main body 11, and is configured to connect the bracket 201 to the main body 11 and absorb the vibration transmitted from the vehicle 1 toward the bracket 201.

A fixed point 113 where the first positioning plate 110 of each vibration damping module is fixed on the main body 11 and a fixed point 123 where the second positioning plate 120 is fixed on the mounted object 20 are positioned between the first damping ball 130 and the second damping ball 140. Therefore, the vibration generated when the vehicle 1 operates is first transmitted to the fixed point 113, then transmitted from the fixed point 113 toward the first end 111 and the second end 112, and then absorbed by the first damping ball 130 and the second damping ball 140.

On the other hand, the virtual line L1 between the fixed point 113 where the first positioning plate 110 of each vibration damping module is fixed on the main body 11 and the fixed point 123 where the second positioning plate 120 is fixed on the mounted object 20 is perpendicular to the first positioning plate 110 and the second positioning plate 120. In a state where the mounted object 20 is positioned on a side of the main body 11 facing the ground, the weight of the mounted object 20 is applied to the first damping ball 130 and the second damping ball 140 via the second positioning plate 120, so that the first damping ball 130 and the second damping ball 140 are in a stretched state under the gravitational force of the mounted object 20 to enhance the ability to absorb vibration.

As shown in FIGS. 1B-1D, in each vibration damping module, a distance S1 between a center of the first damping ball 130 and the fixed point 113 where the first positioning plate 110 is fixed on the main body 11 is greater than a distance S2 between a center of the second damping ball 140 and the fixed point 113 where the first positioning plate 110 is fixed on the main body 11, and a distance S3 between the center of the first damping ball 130 and the fixed point 123 where the second positioning plate 120 is fixed on the mounted object 20 is greater than a distance S4 between the center of the second damping ball 140 and the fixed point 123 where the second positioning plate 120 is fixed on the mounted object 20.

Since the distance S2 for transmitting the vibration from the vehicle 1 from the fixed point 113 toward the center of the second damping ball 140 is shorter than the distance S1 for transmitting from the fixed point 113 toward the center of the first damping ball 130, a shorter moment arm is formed between the fixed point 113 and the center of the second damping ball 140, so that a larger proportion of the vibration transmitted from the vehicle 1 to the first positioning plate 110 is absorbed by the second damping ball 140.

In other embodiments, the distances between the centers of the first damping ball 130 and the second damping ball 140 and the fixed points 113, 123 may also be adjusted to be the same. For example, in each vibration damping module, the distance S1 between the center of the first damping ball 130 and the fixed point 113 where the first positioning plate 110 is fixed on the main body 11 may be equal to the distance S3 between the center of the first damping ball 130 and the fixed point 123 where the second positioning plate 120 is fixed on the mounted object 20, and the distance S2 between the center of the second damping ball 140 and the fixed point 113 where the first positioning plate 110 is fixed on the main body 11 may be equal to the distance S4 between the center of the second damping ball 140 and the fixed point 123 where the second positioning plate 120 is fixed on the mounted object 20.

FIG. 1E is a schematic bottom view of the mounted object and the vibration damping structure for the vehicle of FIG. 1B, with the external contour of the flight control box 202 shown in dashed lines to present the specific configuration of the inertial measurement unit 203 and the multiple vibration damping modules. Referring to FIGS. 1B, 1C, and 1E, in the embodiment, the fixed point 123 where the second positioning plate 120 of the first vibration damping module 101 is fixed on the mounted object 20 and the fixed point 123 where the second positioning plate 120 of the second vibration damping module 102 is fixed on the mounted object 20 are connected to form a first virtual line 105, and the fixed point 123 where the second positioning plate 120 of the third vibration damping module 103 is fixed on the mounted object 20 and the fixed point 123 where the second positioning plate 120 of the fourth vibration damping module 104 is fixed on the mounted object 20 are connected to form a second virtual line 106 parallel to the first virtual line 105.

The multiple first damping balls 130 of the first vibration damping module 101, the second vibration damping module 102, the third vibration damping module 103, and the fourth vibration damping module 104 fall within a virtual area 107 between the first virtual line 105 and the second virtual line 106, and the multiple second damping balls 140 of the first vibration damping module 101, the second vibration damping module 102, the third vibration damping module 103, and the fourth vibration damping module 104 fall outside the virtual area 107.

As shown in FIGS. 1C-1E, since the distance S2 for transmitting the vibration from the vehicle 1 from the fixed point 113 to the center of the second damping ball 140 is shorter than the distance S1 for transmitting from the fixed point 113 to the center of the first damping ball 130, a shorter moment arm is formed between the fixed point 113 and the center of the second damping ball 140, so that a larger proportion of the vibration transmitted from the vehicle 1 to the first positioning plate 110 is absorbed by the second damping ball 140. That is, most of the vibration is absorbed by the second damping balls 140 located outside the virtual area 107, thereby reducing the vibration transmitted to the portion of the flight control box 202 that falls within the virtual area 107.

As shown in FIG. 1E, along a direction D1 perpendicular to the first virtual line 105 and from an outside of the virtual area 107 to an inside of the virtual area 107, a shortest distance S5 between the second positioning plate 120 of the first vibration damping module 101 and the second positioning plate 120 of the second vibration damping module 102 gradually increases. In addition, a distance S6 between the center of the first damping ball 130 of the first vibration damping module 101 and the center of the first damping ball 130 of the second vibration damping module 102 is greater than a distance S7 between the center of the second damping ball 140 of the first vibration damping module 101 and the center of the second damping ball 140 of the second vibration damping module 102.

On the other hand, along a direction D2 perpendicular to the second virtual line 106 and from the outside of the virtual area 107 to the inside of the virtual area 107, a shortest distance S8 between the second positioning plate 120 of the third vibration damping module 103 and the second positioning plate 120 of the fourth vibration damping module 104 gradually increases. In addition, a distance S9 between the center of the first damping ball 130 of the third vibration damping module 103 and the center of the first damping ball 130 of the fourth vibration damping module 104 is greater than the distance S10 between the center of the second damping ball 140 of the third vibration damping module 103 and the center of the second damping ball 140 of the fourth vibration damping module 104.

Based on expanding the distance between the center of the first damping ball 130 of the first vibration damping module 101 and the center of the first damping ball 130 of the second vibration damping module 102 that fall within the virtual area 107 and the distance between the center of the first damping ball 130 of the third vibration damping module 103 and the center of the first damping ball 130 of the fourth vibration damping module 104, it helps to enhance the vibration damping effect in the direction parallel to the first virtual line 105 and the second virtual line 106.

As shown in FIG. 1E, the distance S6 between the center of the first damping ball 130 of the first vibration damping module 101 and the center of the first damping ball 130 of the second vibration damping module 102 is greater than the distance S9 between the center of the first damping ball 130 of the third vibration damping module 103 and the center of the first damping ball 130 of the fourth vibration damping module 104. In addition, the distance S7 between the center of the second damping ball 140 of the first vibration damping module 101 and the center of the second damping ball 140 of the second vibration damping module 102 is greater than the distance S10 between the center of the second damping ball 140 of the third vibration damping module 103 and the center of the second damping ball 140 of the fourth vibration damping module 104.

In the embodiment, the mounted object 20 further includes an inertial measurement unit 203 disposed within the flight control box 202, where the inertial measurement unit 203 is located within the virtual area 107, and a distance S11 between the inertial measurement unit 203 and the first virtual line 105 is greater than a distance S12 between the inertial measurement unit 203 and the second virtual line 106. Furthermore, the inertial measurement unit 203 is disposed within the virtual area 107 close to the third vibration damping module 103 and the fourth vibration damping module 104, and is substantially located between the third vibration damping module 103 and the fourth vibration damping module 104. Compared to the first vibration damping module 101 and the second vibration damping module 102, the third vibration damping module 103 and the fourth vibration damping module 104 adopt a more compact configuration, which helps to enhance the vibration damping effect for the inertial measurement unit 203.

As shown in FIGS. 1C-1E, since the distance S2 for transmitting the vibration from the vehicle 1 from the fixed point 113 toward the center of the second damping ball 140 is shorter than the distance S1 for transmitting from the fixed point 113 toward the center of the first damping ball 130, a shorter moment arm is formed between the fixed point 113 and the center of the second damping ball 140, so that a larger proportion of the vibration transmitted from the vehicle 1 to the first positioning plate 110 is absorbed by the second damping ball 140. That is, most of the vibration is absorbed by the second damping ball 140 located outside the virtual area 107, thereby reducing the vibration transmitted to the inertial measurement unit 203 that falls within the virtual area 107.

FIG. 1F is a schematic exploded view of the vibration damping module of FIG. 1B. Referring to FIGS. 1B, 1D, and 1F, the first damping ball 130 of each vibration damping module includes a body portion 131, a first slot portion 132 located at one end of the body portion 131, a first blocking portion 133 connected to the body portion 131 by the first slot portion 132, a second slot portion 134 located at the other end of the body portion 131, and a second blocking portion 135 connected to the body portion 131 by the second slot portion 134. In addition, the second damping ball 140 of each vibration damping module includes a body portion 141, a first slot portion 142 located at one end of the body portion 141, a first blocking portion 143 connected to the body portion 141 by the first slot portion 142, a second slot portion 144 located at the other end of the body portion 141, and a second blocking portion 145 connected to the body portion 141 by the second slot portion 144.

The first damping ball 130 and the second damping ball 140 may be made of rubber, and the body portion 131 and the body portion 141 may have hollow structures to enhance the vibration damping effect. On the other hand, the first end 111 and the second end 112 of the first positioning plate 110 of each vibration damping module are respectively sleeved onto the first slot portion 132 of the first damping ball 130 and the first slot portion 142 of the second damping ball 140, and the first end 121 and the second end 122 of the second positioning plate 120 of each vibration damping module are respectively sleeved onto the second slot portion 134 of the first damping ball 130 and the second slot portion 144 of the second damping ball 140.

As shown in FIGS. 1D and 1F, the first end 111 and the second end 112 of the first positioning plate 110 respectively have positioning holes corresponding to the first slot portion 132 of the first damping ball 130 and the first slot portion 142 of the second damping ball 140. An inner diameter of the positioning hole at the first end 111 of the first positioning plate 110 is smaller than an outer diameter of the first blocking portion 133 of the first damping ball 130, and an inner diameter of the positioning hole at the second end 112 of the first positioning plate 110 is smaller than an outer diameter of the first blocking portion 143 of the second damping ball 140.

On the other hand, the first end 121 and the second end 122 of the second positioning plate 120 respectively have positioning holes corresponding to the second slot portion 134 of the first damping ball 130 and the second slot portion 144 of the second damping ball 140. An inner diameter of the positioning hole at the first end 121 of the second positioning plate 120 is smaller than an outer diameter of the second blocking portion 135 of the first damping ball 130, and an inner diameter of the positioning hole at the second end 122 of the second positioning plate 120 is smaller than an outer diameter of the second blocking portion 145 of the second damping ball 140.

After the first end 111 and the second end 112 of the first positioning plate 110 are respectively sleeved onto the first slot portion 132 of the first damping ball 130 and the first slot portion 142 of the second damping ball 140, the first blocking portion 133 of the first damping ball 130 and the first blocking portion 143 of the second damping ball 140 respectively pass through the first end 111 and the second end 112, so that the first positioning plate 110 is positioned between the first blocking portion 133 and the body portion 131 of the first damping ball 130, and simultaneously positioned between the first blocking portion 143 and the body portion 141 of the second damping ball 140.

After the first end 121 and the second end 122 of the second positioning plate 120 are respectively sleeved onto the second slot portion 134 of the first damping ball 130 and the second slot portion 144 of the second damping ball 140, the second blocking portion 135 of the first damping ball 130 and the second blocking portion 145 of the second damping ball 140 respectively pass through the first end 121 and the second end 122, so that the second positioning plate 120 is positioned between the second blocking portion 135 and the body portion 131 of the first damping ball 130, and simultaneously positioned between the second blocking portion 145 and the body portion 141 of the second damping ball 140.

As shown in FIGS. 1C and 1D, the first blocking portion 133 of the first damping ball 130 and the first blocking portion 143 of the second damping ball 140 of each vibration damping module may contact the main body 11 of the vehicle 1. Therefore, the vibration generated when the vehicle 1 operates may be directly transmitted to the first damping ball 130 and the second damping ball 140 to be absorbed, thereby enhancing the vibration damping effect for the mounted object 20.

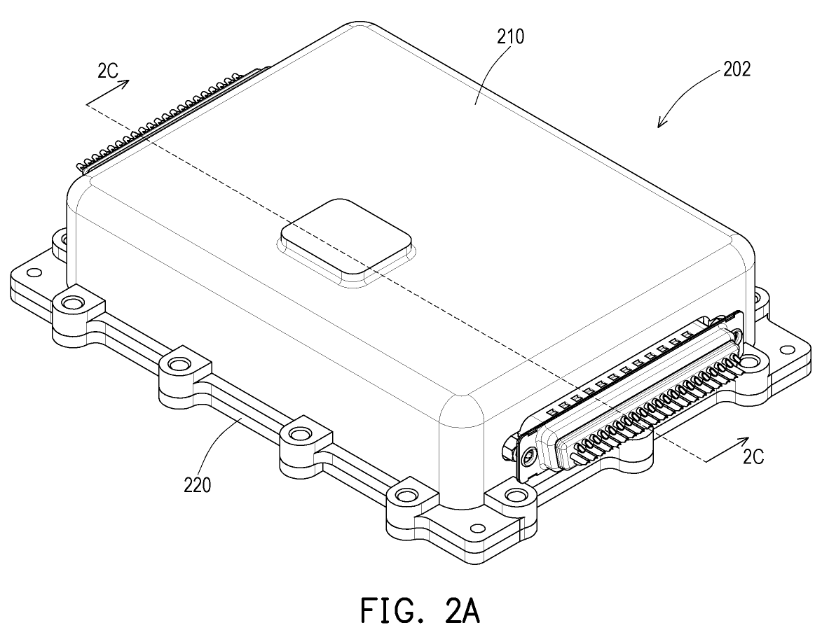

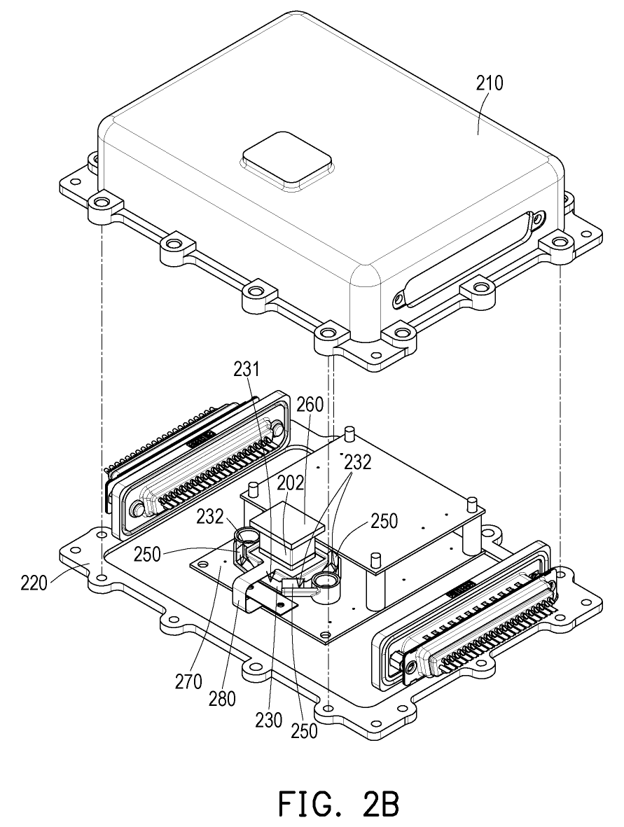

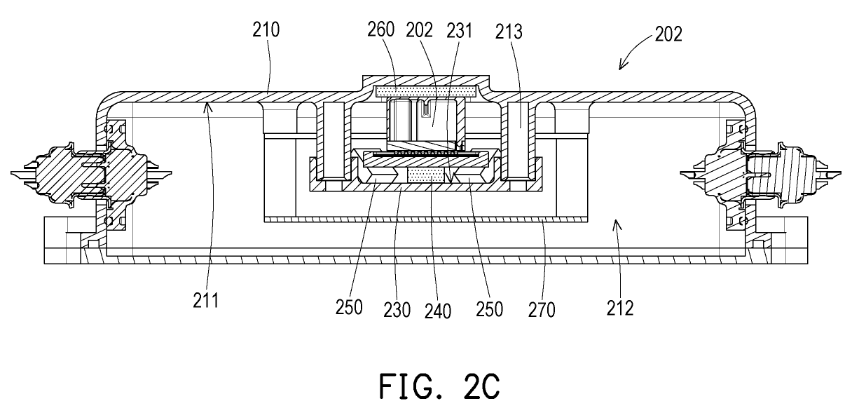

FIG. 2A is a schematic view of the flight control box of FIG. 1B. FIG. 2B is a schematic exploded view of the flight control box of FIG. 2A. FIG. 2C is a schematic cross-sectional view along line segment FIGS. 2C-2C of 2A. Referring to FIGS. 2A-2C, in the embodiment, the flight control box 202 includes a first housing 210, a second housing 220, a support member 230, a first vibration damping body 240, a plurality of second vibration damping bodies 250, a third vibration damping body 260, and an inertial measurement unit 203. The first housing 210 has an inner surface 211, and the inner surface 211 forms an accommodation space 212. The second housing 220 is disposed on the first housing 210 and covers the accommodation space 212. In addition, the support member 230 is disposed within the accommodation space 212. The first housing 210 has a positioning pin 213 extending from the inner surface 211 toward the second housing 220, and the support member 230 is connected to the positioning pin 213 to remain suspended in the accommodation space 212.

As shown in FIGS. 2B and 2C, the support member 230 has a support surface 231 and a plurality of inclined surfaces 232 facing the inner surface 211, and the plurality of inclined surfaces 232 are connected to the support surface 231. Specifically, the first vibration damping body 240 is disposed on the support surface 231, and the plurality of second vibration damping bodies 250 are respectively disposed on the plurality of inclined surfaces 232. In addition, the third vibration damping body 260 is disposed on the inner surface 211, that is, specifically disposed on an area of the inner surface 211 corresponding to the support surface 231.

The first vibration damping body 240 and the third vibration damping body 260 respectively abut against two opposite sides of the inertial measurement unit 203 to absorb the vibration transmitted to the first housing 210 and the support member 230. On the other hand, the plurality of second vibration damping bodies 250 surround the inertial measurement unit 203 and abut against a side edge of the side of the inertial measurement unit 203 that abuts the first vibration damping body 240, so as to absorb the vibration transmitted to the support member 230. Furthermore, the first vibration damping body 240, the plurality of second vibration damping bodies 250, and the third vibration damping body 260 may be made of foam, which not only enhances the vibration damping effect for the inertial measurement unit 203, but also stably positions the inertial measurement unit 203 on the support member 230 to prevent the inertial measurement unit 203 from generating offset or shaking.

As shown in FIGS. 2B and 2C, the flight control box 202 further includes a flight control board 270. The flight control board 270 is disposed within the accommodation space 212, and the support member 230 is located between the flight control board 270 and the inner surface 211. The support member 230 remains suspended in the accommodation space 212, and the flight control board 270 is separated from the support member 230 to block the path of vibration transmitted to the inertial measurement unit 203 by the flight control board 270. On the other hand, the flight control box 202 further includes a cable 280. The cable 280 is located within the accommodation space 212 and extends from the inertial measurement unit 203 to the flight control board 270 to be electrically connected to the inertial measurement unit 203 and the flight control board 270.

In summary, in the vibration damping structure for the vehicle and the vehicle of the disclosure, the mounted object is fixed to the vehicle by a plurality of vibration damping modules, so that the plurality of vibration damping modules absorb the vibration generated when the vehicle operates, thereby significantly reducing the degree of vibration transmitted from the main body of the vehicle to the mounted object to avoid failure, damage, or functional failure of the mounted object due to vibration. In detail, each vibration damping module includes a first positioning plate fixed to the vehicle, a second positioning plate fixed to the mounted object, and a first damping ball and a second damping ball that separate the first positioning plate and the second positioning plate. The vibration generated when the vehicle operates may be transmitted from the first positioning plate to the first damping ball and the second damping ball to be absorbed, or directly transmitted to the first damping ball and the second damping ball to be absorbed, thereby enhancing the vibration damping effect for the mounted object.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. The use of “at least one of...and...” thereof herein may include “one or more of the items contained in the list”. For example, the use of “at least one of A and B” thereof herein may include only A, or only B, or A and B. Similarly, the use of “at least one of A, B, and C” thereof herein may include only A, or only B, or only C, or any combination of A, B, and C. Moreover, these claims may refer to use “first”, “second”, etc. following with noun or element. Such terms should be understood as a nomenclature and should not be construed as giving the limitation on the number of the elements modified by such nomenclature unless specific number has been given. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A vibration damping structure for a vehicle, configured to connect a mounted object to a main body of the vehicle, the vibration damping structure for the vehicle comprising:
a plurality of vibration damping modules, wherein each of the plurality of vibration damping modules comprises:
a first positioning plate, configured to be fixed to the main body, wherein the first positioning plate has a first end and a second end that are opposite to each other;
a second positioning plate, located at a side of the first positioning plate away from the main body, and configured to be fixed to the mounted object, wherein the second positioning plate has a first end and a second end that are opposite to each other;
a first damping ball, configured to contact the main body, wherein the first end of the first positioning plate and the first end of the second positioning plate are respectively sleeved onto two opposite ends of the first damping ball; and
a second damping ball, configured to contact the main body, wherein the second end of the first positioning plate and the second end of the second positioning plate are respectively sleeved onto two opposite ends of the second damping ball.

2. The vibration damping structure for the vehicle according to claim 1, wherein a fixed point where the first positioning plate of each of the plurality of vibration damping modules is fixed on the main body and a fixed point where the second positioning plate of each of the plurality of vibration damping modules is fixed on the mounted object are located between the first damping ball and the second damping ball.

3. The vibration damping structure for the vehicle according to claim 1, wherein a virtual line between a fixed point where the first positioning plate of each of the plurality of vibration damping modules is fixed on the main body and a fixed point where the second positioning plate of each of the plurality of vibration damping modules is fixed on the mounted object is perpendicular to the first positioning plate and the second positioning plate.

4. The vibration damping structure for the vehicle according to claim 1, wherein a distance between a center of the first damping ball of each of the plurality of vibration damping modules and a fixed point where the first positioning plate of each of the plurality of vibration damping modules is fixed on the main body is greater than a distance between a center of the second damping ball of each of the plurality of vibration damping modules and the fixed point where the first positioning plate of each of the plurality of vibration damping modules is fixed on the main body, and a distance between the center of the first damping ball of each of the plurality of vibration damping modules and a fixed point where the second positioning plate of each of the plurality of vibration damping modules is fixed on the mounted object is greater than a distance between the center of the second damping ball of each of the plurality of vibration damping modules and the fixed point where the second positioning plate of each of the plurality of vibration damping modules is fixed on the mounted object.

5. The vibration damping structure for the vehicle according to claim 1, wherein the plurality of vibration damping modules comprise a first vibration damping module, a second vibration damping module, a third vibration damping module, and a fourth vibration damping module, a fixed point where the second positioning plate of the first vibration damping module is fixed on the mounted object and a fixed point where the second positioning plate of the second vibration damping module is fixed on the mounted object are connected to form a first virtual line, a fixed point where the second positioning plate of the third vibration damping module is fixed on the mounted object and a fixed point where the second positioning plate of the fourth vibration damping module is fixed on the mounted object are connected to form a second virtual line parallel to the first virtual line, the first damping balls of the first vibration damping module, the second vibration damping module, the third vibration damping module, and the fourth vibration damping module fall within a virtual area between the first virtual line and the second virtual line, and the second damping balls of the first vibration damping module, the second vibration damping module, the third vibration damping module, and the fourth vibration damping module fall outside the virtual area.

6. The vibration damping structure for the vehicle according to claim 5, wherein along a direction perpendicular to the first virtual line and from an outside of the virtual area to an inside of the virtual area, a shortest distance between the second positioning plate of the first vibration damping module and the second positioning plate of the second vibration damping module gradually increases.

7. The vibration damping structure for the vehicle according to claim 5, wherein a distance between a center of the first damping ball of the first vibration damping module and a center of the first damping ball of the second vibration damping module is greater than a distance between a center of the second damping ball of the first vibration damping module and a center of the second damping ball of the second vibration damping module.

8. The vibration damping structure for the vehicle according to claim 5, wherein along a direction perpendicular to the second virtual line and from an outside of the virtual area to an inside of the virtual area, a shortest distance between the second positioning plate of the third vibration damping module and the second positioning plate of the fourth vibration damping module gradually increases.

9. The vibration damping structure for the vehicle according to claim 5, wherein a distance between a center of the first damping ball of the third vibration damping module and a center of the first damping ball of the fourth vibration damping module is greater than a distance between a center of the second damping ball of the third vibration damping module and a center of the second damping ball of the fourth vibration damping module.

10. The vibration damping structure for the vehicle according to claim 5, wherein a distance between a center of the first damping ball of the first vibration damping module and a center of the first damping ball of the second vibration damping module is greater than a distance between a center of the first damping ball of the third vibration damping module and a center of the first damping ball of the fourth vibration damping module.

11. The vibration damping structure for the vehicle according to claim 5, wherein a distance between a center of the second damping ball of the first vibration damping module and a center of the second damping ball of the second vibration damping module is greater than a distance between a center of the second damping ball of the third vibration damping module and a center of the second damping ball of the fourth vibration damping module.

12. The vibration damping structure for the vehicle according to claim 1, wherein the first damping ball and the second damping ball of each of the plurality of vibration damping modules respectively comprises a body portion, a first slot portion located at an end of the body portion, a first blocking portion connected to the body portion by the first slot portion, a second slot portion located at the other end of the body portion, a second blocking portion connected to the body portion by the second slot portion, the first end and the second end of the first positioning plate of each of the plurality of vibration damping modules are respectively sleeved onto the first slot portion of the first damping ball and the first slot portion of the second damping ball, and the first end and the second end of the second positioning plate of each of plurality of the vibration damping modules are respectively sleeved onto the second slot portion of the first damping ball and the second slot portion of the second damping ball.

13. The vibration damping structure for the vehicle according to claim 12, wherein the first blocking portion of the first damping ball and the first blocking portion of the second damping ball of each of the plurality of vibration damping modules contact the main body of the vehicle.

14. A vehicle, comprising:
a main body; and
a vibration damping structure for the vehicle, disposed on the main body, the vibration damping structure for the vehicle comprising:
a plurality of vibration damping modules, wherein each of the plurality of vibration damping modules comprises:
a first positioning plate, fixed to the main body, wherein the first positioning plate has a first end and a second end that are opposite to each other;
a second positioning plate, located at a side of the first positioning plate away from the main body, wherein the second positioning plate has a first end and a second end that are opposite to each other;
a first damping ball, contacting the main body, wherein the first end of the first positioning plate and the first end of the second positioning plate are respectively sleeved onto two opposite ends of the first damping ball; and
a second damping ball, contacting the main body, wherein the second end of the first positioning plate and the second end of the second positioning plate are respectively sleeved onto two opposite ends of the second damping ball.

15. The vehicle according to claim 14, further comprising:
a mounted object, located at a side of the second positioning plate away from the main body, wherein the mounted object is fixed to the second positioning plate.

16. The vehicle according to claim 15, wherein the plurality of vibration damping modules comprise a first vibration damping module, a second vibration damping module, a third vibration damping module, and a fourth vibration damping module, a fixed point where the second positioning plate of the first vibration damping module is fixed on the mounted object and a fixed point where the second positioning plate of the second vibration damping module is fixed on the mounted object are connected to form a first virtual line, a fixed point where the second positioning plate of the third vibration damping module is fixed on the mounted object and a fixed point where the second positioning plate of the fourth vibration damping module is fixed on the mounted object are connected to form a second virtual line parallel to the first virtual line, the first damping balls of the first vibration damping module, the second vibration damping module, the third vibration damping module, and the fourth vibration damping module fall within a virtual area between the first virtual line and the second virtual line, and the second damping balls of the first vibration damping module, the second vibration damping module, the third vibration damping module, and the fourth vibration damping module fall outside the virtual area.

17. The vehicle according to claim 16, wherein the mounted object comprises an inertial measurement unit, and the inertial measurement unit is located within the virtual area.

18. The vehicle according to claim 17, wherein a distance between the inertial measurement unit and the first virtual line is greater than a distance between the inertial measurement unit and the second virtual line.

19. The vehicle according to claim 15, wherein the first damping ball and the second damping ball of each of the plurality of vibration damping modules are in a stretched state under a gravitational force of the mounted object.

20. The vehicle according to claim 15, wherein the mounted object comprises a bracket, and the second positioning plate of each of the plurality of vibration damping modules is fixed to the bracket.

21. The vehicle according to claim 20, wherein the mounted object further comprises a flight control box fixed to the bracket, and the bracket is located between the flight control box and each of the plurality of vibration damping modules.

22. The vehicle according to claim 21, wherein the flight control box comprises:
a first housing, having an inner surface, wherein the inner surface forms an accommodation space;
a second housing, disposed on the first housing, and covering the accommodation space;
a support member, disposed within the accommodation space, wherein the support member has a support surface and a plurality of inclined surfaces facing the inner surface, and the plurality of inclined surfaces are connected to the support surface;
a first vibration damping body, disposed on the support surface;
a plurality of second vibration damping bodies, respectively disposed on the plurality of inclined surfaces;
a third vibration damping body, disposed on the inner surface; and
an inertial measurement unit, wherein the first vibration damping body and the third vibration damping body respectively abut against two opposite sides of the inertial measurement unit, and the plurality of second vibration damping bodies surround the inertial measurement unit and abut against a side edge of the side of the inertial measurement unit that abuts the first vibration damping body.

23. The vehicle according to claim 22, wherein the flight control box further comprises:
a flight control board, disposed within the accommodation space, wherein the support member is located between the flight control board and the inner surface, and the flight control board is separated from the support member.

24. The vehicle according to claim 23, wherein the flight control box further comprises:
a cable, located within the accommodation space, and electrically connected to the inertial measurement unit and the flight control board.

25. The vehicle according to claim 22, wherein a material of the first vibration damping body, a material of the plurality of second vibration damping bodies, and a material of the third vibration damping body comprise foam, and a material of the first damping ball and a material of the second damping ball of each of the plurality of vibration damping modules comprise rubber.
